(19) United States
(12) Patent Application Publication
(10) Pub. No.: US 2025/0259936 A1
(43) Pub. Date: Aug. 14, 2025

(54) ELECTRONIC MODULE, METHOD OF MANUFACTURING ELECTRONIC MODULE AND ELECTRONIC MODULE MANUFACTURING DEVICE

(71) Applicant: SHINDENGEN ELECTRIC MANUFACTURING CO., LTD., Tokyo (JP)

(72) Inventors: Soichiro UMEDA, Saitama (JP); Atsushi KYUTOKU, Saitama (JP)

(21) Appl. No.: 19/052,276

(22) Filed: Feb. 13, 2025

(30) Foreign Application Priority Data
Feb. 14, 2024 (JP) 2024-020370

(51) Int. Cl. H01L 23/538; H01L 21/48; H01L 21/56; H01L 23/31; H01L 25/07; H01R 12/58

(52) U.S. Cl. CPC H01L 23/5385; H01L 21/4846; H01L 21/56; H01L 23/3107; H01L 23/5386; H01L 25/072; H01R 12/585

(57) ABSTRACT

An electronic module includes: a board; electronic elements disposed on the board; and a flat-plate-shaped power terminal being erected upright from the board, wherein the board, the electronic elements and the power terminal are sealed by a sealing member, and the power terminal is configured such that the power terminal is electrically connected with the board, at least a distal end portion of the power terminal protrudes from the sealing member, and a depressed portion that is dented than the other portions is disposed at a position where the power terminal is brought into contact with a surface of the sealing member.

### CROSS REFERENCE TO RELATED APPLICATIONS

This application claims priority to Japanese Patent Application No. 2024-20370, filed on Feb. 14, 2024, which is expressly incorporated herein by reference in its entirety.

### TECHNICAL FIELD

The present invention relates to an electronic module, a method of manufacturing an electronic module, and an electronic module manufacturing device.

### BACKGROUND ART

Conventionally, there has been known an electronic module that includes pin terminals that are erected upright from a board, and such a structure is sealed by a sealing member (for example, see patent literature 1).

In a conventional electronic module 900, as illustrated in FIG. 11, pin terminals 972, 974 protrude from a seal resin 990 and hence, resin sealing is performed using a die that includes a pair of slide portions 922. To be more specific, in a manufacturing process of the electronic module, the pin terminals 972, 974 are disposed on a die and, thereafter, the pair of slide portions 922 is made to slide so as to clamp the pin terminals 972, 974 and hence, it is possible to prevent the seal resin 990 from flowing out from the pair of slide portions 922 thus performing resin sealing. On the pin terminals 972, 974 of the conventional electronic module 900, recesses 963 that correspond to distal end portions of the slide portion 922 are formed.

### PRIOR ART LITERATURE

### Patent Literature

[Patent Literature 1] WIPO 2020/129195

### SUMMARY OF INVENTION

### Technical Problem

Recently, there has been a demand for an electronic module compatible with an electric equipment in which a large current flows. To satisfy such a demand, a case is considered where a plate-shaped power terminal having a current path of a relatively large cross-sectional area is used in place of a pin terminal. However, in the case where the plate-shaped power terminal is used, a contact surface between a slide portion and the power terminal is large and a shear droop surface or a fracture is formed at the time of manufacturing the power terminal due to shearing of a plate member and hence, there is a concern that a gap is formed between a die (slide portion) and the power terminal whereby there exists a drawback that leakage of a resin may occur.

The present invention has been made in view of the above-mentioned circumstances, and it is an object of the present invention to provide an electronic module where leakage of a resin minimally occurs in a sealing step in spite of the use of a plate-shaped power terminal.

### Solution to Problem

An electronic module according to the present invention is an electronic module that includes: a board; an electronic element disposed on the board; and a flat-plate-shaped power terminal being erected upright from the board, wherein the board, the electronic element and the power terminal are sealed by a sealing member, and the power terminal is configured such that at least a distal end portion of the power terminal protrudes from the sealing member, and the power terminal includes a depressed portion that is dented compared to other portions of the power terminal at a position where the power terminal is brought into contact with a surface of the sealing member.

A method of manufacturing an electronic module according to the present invention includes: an assembled body forming step of forming an assembled body including a board, an electronic element and a power terminal having a flat plate shape by erecting upright the power terminal on the board on which the electronic element is disposed; an accommodating step of accommodating the board, the electronic element and the first part of the power terminal on a board side in a first cavity of a die, and accommodating a second part of the power terminal on a distal end side into a power terminal accommodating hole that extends from an inner surface of the first cavity; and a sealing step of sealing, after the accommodating step, the board, the electronic element, and the first part of the power terminal by making a sealing material flow into the first cavity, wherein in the accommodating step, the second part of the power terminal is inserted into the power terminal accommodating hole and, thereafter, distal end portions of a pair of slide portions mounted on the die are made to protrude from an inner periphery of the power terminal accommodating hole so as to clamp the power terminal by the pair of slide portions so that the distal end portion of the second part of the power terminal is separated from the first cavity and the distal end portions of the pair of slide portions bite into an outer periphery of the second part of the power terminal whereby a depressed portion is formed on an outer periphery of the second part of the power terminal.

A manufacturing device of an electronic module according to the present invention is a manufacturing device of an electronic module for carrying out the method of manufacturing an electronic module according to the preset invention. The manufacturing device includes: a first die that has the power terminal insertion hole and includes the pair of slide portions; and a second die that opposedly faces the first die, wherein one side surface of the power terminal is a shear droop surface where a shear droop is formed at an end portion, the other surface of the power terminal is a burr surface that is contiguously formed with a fracture surface of a side surface, and as viewed in a plan view, a recessed portion that corresponds to a cross section of the power terminal is formed on distal end portions of the pair of slide portions respectively, with respect to the pair of slide portions, a shape of a bottom of the recessed portion of the slide portion that is brought into contact with the shear droop surface has a shape that corresponds to the shape of the shear droop surface, and with respect to the pair of slide portions, a shape of a bottom of the recessed portion of the slide portion that is brought into contact with the burr surface is formed such that a protruding portion is formed on both side wall sides of the recessed portion.

### Advantageous Effects of the Present Invention

According to the electronic module of the present invention, the power terminal has the depressed portion that is dented than other portions at the position where the power terminal is brought into contact with the surface of the sealing member. Accordingly, at the time of performing resin sealing using the die, a gap minimally occurs between the die (slide portion) and the power terminal and hence, leakage of a resin can be prevented. As a result, the electronic module according to the present invention, although the electronic module uses the plate-shaped power terminal, becomes an electronic module where leakage of a resin minimally occurs at the time of performing the sealing step.

According to the method of manufacturing an electronic module and the manufacturing device according to the present invention, by clamping the power terminal by the pair of slide portions, the distal end portion of the power terminal is separated from the first cavity and, at the same time, the distal end portions of the pair of slide portions bite into the outer periphery of the second forming the part of the power terminal thus depressed portion and hence, a gap minimally occurs between the die (slide portion) and the power terminal whereby it is possible to easily prevent the occurrence of leakage of a resin.

### BRIEF DESCRIPTION OF DRAWINGS

FIG. 1A and FIG. 1B are perspective views of illustrating an electronic module 100 according to an embodiment. FIG. 1A is a perspective view of the electronic module 100, and FIG. 1B is a front view of the electronic module 100.

FIG. 2A to FIG. 2C are views illustrating an internal structure of the electronic module 100 according to the embodiment. FIG. 2A is a front view where the illustration of a sealing member 190 is omitted from the electronic module 100, FIG. 2B is a plan view where the illustration of the sealing member 190 is omitted from the electronic module 100, and FIG. 2C is a plan view where the illustration of the sealing member 190, a first connection frame 132, a second connection frame 142 and an internal connection frame 152 are omitted.

FIG. 3A to FIG. 3D are views for describing a power terminal 160 according to the embodiment. FIG. 3A is a front view of the power terminal 160, FIG. 3B is a plan view of the power terminal 160, FIG. 3C is an enlarged planar cross-sectional view illustrating an A1-A1 cross section in FIG. 3A, and FIG. 3D is an enlarged planar cross-sectional view illustrating an A2-A2 cross section in FIG. 3A.

FIG. 4A to FIG. 4D are views illustrating steps of manufacturing the power terminal 160 according to the embodiment. FIG. 4A to FIG. 4D are respective step views.

FIG. 5 is a flowchart illustrating a method of manufacturing an electronic module according to the embodiment.

FIG. 6A and FIG. 6B are views illustrating a step of accommodating an assembled body in a die 1. FIG. 6A is a front cross-sectional view of the step of accommodating the assembled body in the die 1, FIG. 6B is a side cross-sectional view at the time of accommodating the assembled body in the die 1.

FIG. 7A and FIG. 7B are views illustrating a step of clamping the power terminal 160 by a pair of slide portions 24. FIG. 7A is a cross-sectional front view of a step of clamping the power terminal 160 by the pair of slide portions 24, FIG. 7B is a cross-sectional side view of the step of clamping the power terminal 160 by the pair of slide portions 24.

FIG. 8 is a plan view illustrating a mode where the slide portions 24 clamp the power terminal 160 in an accommodating step.

FIG. 9A and FIG. 9B are enlarged plan views of an essential part illustrating the mode where the slide portions 24 clamp the power terminal 160 in the accommodating step.

FIG. 10A and FIG. 10B are views illustrating a mode of a sealing step. FIG. 10A is a cross-sectional front view illustrating the mode of the sealing step, and FIG. 10B is a cross-sectional side view of the sealing step.

FIG. 11 is a cross-sectional view illustrating a resin sealing step in a conventional electronic module. Symbol 910 indicates a board, symbol 920 indicates an electronic element, symbols 932, 942 indicate connection frames, and symbol 952 indicates an internal connection frame.

### DESCRIPTION OF EMBODIMENTS

Hereinafter, an electronic module, a method of manufacturing an electronic module, and an electronic module manufacturing device are described based on an embodiment illustrated in drawings. The embodiments described hereinafter are not intended to limit the invention called for in claims. Further, it is not always the case that all of various constitutional elements and combinations of these constitutional elements described in the embodiment are indispensable as means to solve the problems of the present invention.

### EMBODIMENT

### 1. Electronic Module 100 According to Embodiment.

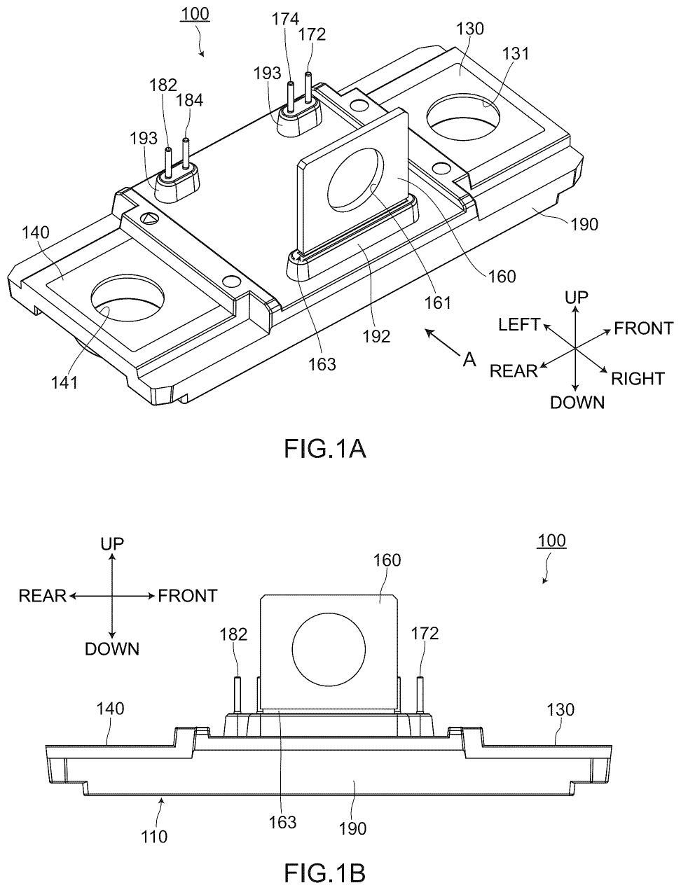

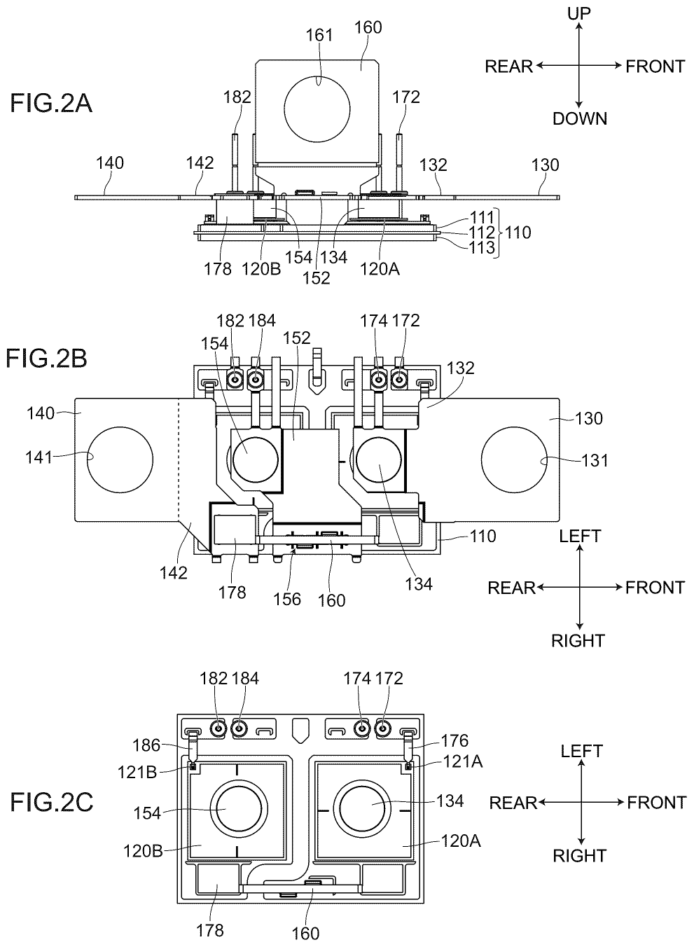

First, the electronic module 100 according to the embodiment is described. The electronic module 100 according to the embodiment includes, as illustrated in FIG. 1A and FIG. 1B and FIG. 2A to FIG. 2C, a board 110, electronic elements 120A, 120B, a first terminal 130, a second terminal 140, a power terminal 160, a first connection frame 132, a second connection frame 142, an internal connection terminal 152 and pin terminals 172, 174, 182, 184.

In the description made hereinafter, the description is made by setting a longitudinal direction of the electronic module 100 as a front-and-rear direction, and a lateral direction as a left-and-right direction. Further, the description is made by setting a height direction of the electronic module 100 as an up-and-down direction. In the description made hereinafter, “front”, “rear”, “left”, “right”, “up”, and “down” are used for the sake of facilitating the description of the present invention, and do not specify the direction that the electronic module 100 is mounted when the electronic module 100 is used.

As illustrated in FIG. 1A and FIG. 1B, resin sealing is applied to the electronic module 100 according to the embodiment using a sealing member 190. Distal end portions of the first terminal 130, the second terminal 140, the power terminal 160, pin terminals 172, 174, 182, 184, and the board 110 (a metal plate 113 for heat radiation) are exposed from the sealing member 190.

As illustrated in FIG. 1A and FIG. 1B and FIG. 2A to FIG. 2C, the electronic module 100 according to the embodiment constitutes a half bridge circuit by connecting the electronic elements (semiconductor elements) 120A, 120B in series. The second terminal 140 is connected to a high voltage outside the electronic module 100, and the first terminal 130 is connected to a reference potential. The power terminal 160 is an intermediate point terminal that is connected to an intermediate point between a source electrode of the electronic element 120A and a drain electrode of the electronic element 120B. A circuit that constitutes the electronic module 100 may be a full bridge circuit, or other suitable circuits.

As illustrated in FIG. 2A, the board 110 is a direct copper bonding board (DCB board) that includes an insulation board (ceramic board) 112, a circuit wiring 111 formed on an upper surface of the insulation board (ceramic board) 112, and a metal plate 113 for heat radiation formed on a lower surface (back surface) of the insulation board (ceramic board) 112. The board 110 may be a suitable board such as a printed circuit board.

The electronic elements 120A, 120B are disposed on a die pad of the circuit wiring 111. The electronic elements 120A, 120B are each formed of a metal-oxide-semiconductor field-effect transistor (MOSFET) where a drain electrode is formed on a board 110 side, and a source electrode and a gate electrode are formed on a side opposite to the board side. The electronic elements 120A, 120B may each be a semiconductor element of a different type such as an IGBT, a triac or a diode, or may be an electronic element other than a semiconductor element such as a capacitor or an inductor. Further, the number of electronic elements 120A, 120B is not limited to two, and may be one or more.

In the electronic element 120A, the source electrode is connected to the first terminal 130 via an internal connection terminal 134 and the first connection frame 132. Further, the source electrode is connected to the pin terminal 174 that functions as a SENSE terminal via a wire, a circuit wiring or the like not illustrated in the drawing. A gate electrode is connected to the pin terminal 172 via a connection element 176 and a circuit wiring. A drain electrode (not illustrated in the drawing) is connected to the power terminal 160 via the circuit wiring 111, and the power terminal 160 is electrically connected to an internal connection frame 152. In the example in FIG. 1A and FIG. 1B, the internal connection terminal 134 has a circular shape in cross section.

In the electronic element 120B, a source electrode is connected to the internal connection frame 152 via an internal connection terminal 154, and the internal connection frame 152 is connected to the power terminal 160. Further, the source electrode is connected to the pin terminal 184 that functions as a SENSE terminal via a wire, a circuit wiring or the like not illustrated in the drawing. A gate electrode is connected to a pin terminal 182 via a connection element 186 and a circuit wiring. A drain electrode (not illustrated in the drawing) is electrically connected to a second terminal 140 via the circuit wiring 111, a connection member 178 and the second connection frame 142. In the example illustrated in FIG. 1A and FIG. 1B, the internal connection terminal 154 has a circular shape in cross section, and the connection member 178 has a rectangular shape in cross section.

As illustrated in FIG. 1A and FIG. 1B and FIG. 2A to FIG. 2C, the first terminal 130 is disposed on a front side of the electronic module 100 in the front-and-rear direction. The first terminal 130 is formed of a plate-shape member that is made of a flat plate material having conductivity, for example, a copper plate. The first terminal 130 has a through hole 131 that penetrates the first terminal 130 in the up-and-down direction. The through hole 131 has a circular shape, for example, as viewed in the up-and-down direction.

The first connection frame 132 is electrically connected with the first terminal 130. The first connection frame 132 is embedded in the sealing member 190. In the electronic module 100, the first connection frame 132 is integrally formed with the first terminal 130 using the same plate material.

The first connection frame 132 includes a through hole (symbol being omitted) that penetrates the first connection frame 132 in the up-and-down direction. The through hole has a circular shape as viewed in the up-and-down direction. An upper end portion of the internal connection terminal 134 engages with the through hole by fitting engagement. The internal connection terminal 134 is fixed to the first connection frame 132 by press-fitting, for example, so as to connect the first connection frame 132 and the source electrode of the electronic element 120A.

The second terminal 140 is disposed on a rear side of the electronic module 100 in the front-and-rear direction. The second terminal 140 is formed of a plate-shape member that is made of a flat plate material having conductivity, for example, a copper plate. The second terminal 140 has a through hole 141 that penetrates the second terminal 140 in the up-and-down direction. The through hole 141 has a circular shape, for example, as viewed in the up-and-down direction.

The second connection frame 142 (internal connection frame) is electrically connected with the second terminal 140. The second connection frame 142 is embedded in the sealing member 190. In the electronic module 100, the second connection frame 142 is integrally formed with the second terminal 140 using the same plate material.

The internal connection frame 152 is a plate-shaped member that has a through hole (symbol being omitted) and an elongated hole 156 (see FIG. 2B) that penetrate the internal connection frame 152 in the up-and-down direction. The internal connection frame 152 supports the power terminal 160 and, at the same time, electrically connects the electronic elements 120A, 120B and the power terminal 160 to each other. The internal connection frame 152 is disposed on the same plane as the first connection frame 132 and the second connection frame 142.

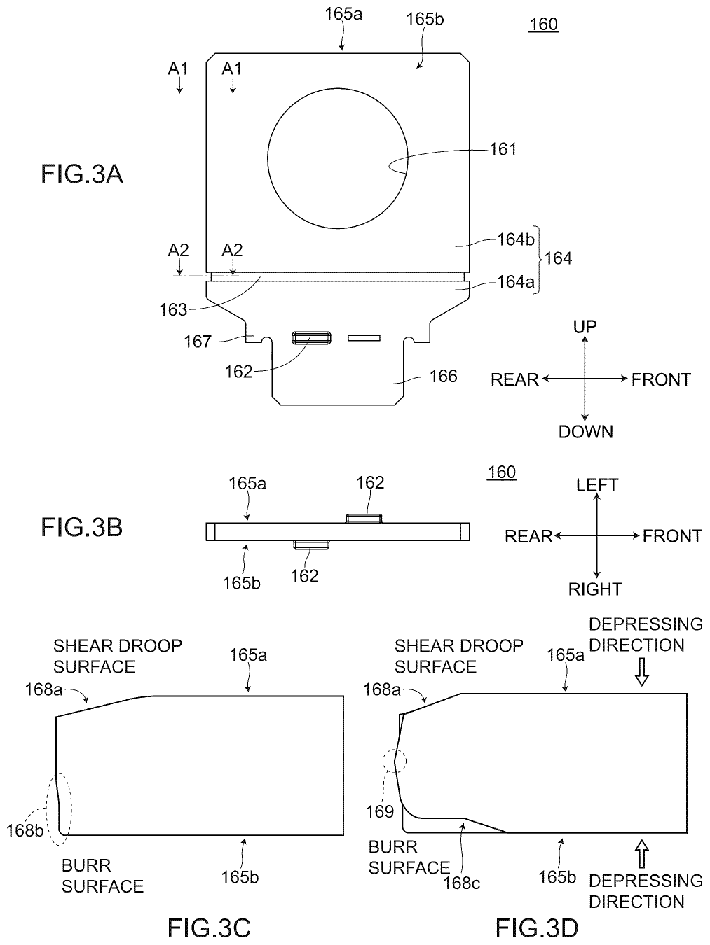

The through hole has a circular shape as viewed in the up-and-down direction, an upper end portion of the internal connection terminal 154 engages with the through hole by fitting engagement. With the use of the internal connection terminal 154, the internal connection frame 152 and the source electrode of the electronic element 120A are connected to each other. The elongated hole 156 extends in the front-and-rear direction, and a first part (see symbol 166 in FIG. 3A to FIG. 3D described later) is press-fitted into the elongated hole 156 of the power terminal 160.

As illustrated in FIG. 1A to FIG. 3D, the power terminal 160 is a flat-plate-shaped member that is erected upright from the board 110. The power terminal 160 is disposed such that the left-and-right direction becomes a plate thickness direction, and is formed in an elongated shape where the up-and-down direction is set as the longitudinal direction. As illustrated in FIG. 3A to FIG. 3D, the power terminal 160 is positioned on a more board side than the internal connection frame 152. The power terminal 160 includes: a first part 166 that is press-fitted into the elongated hole 156; and a second part 164 that is positioned on a side opposite to a board 110 side of the internal connection frame 152, and formed with a larger width than the first part 166.

A distal end of the first part 166 on a board side is electrically connected to the board 110. The first part 166 constitutes a portion of a circuit wiring that connected between the electronic element 120A and the electronic element 120B. The first part 166 is sealed by the sealing member 190. The power terminal 160 may not be directly electrically bonded to the board 110.

The second part 164 is connected to the first part 166. The second part 164 includes: a connection portion 164a where a width (a width in the front-and-rear direction) of the connection portion 164a is gradually widened as the connection portion 164a becomes away from the first part 166 in the left-and-right direction; and an exposed portion 164b (distal end portion) having an approximately rectangular shape that is connected to the connection portion 164a and extends toward an upper side.

The connection portion 164a includes: a support portion 167 that supports the power terminal 160 by being brought into contact with the internal connection frame 152; and protruding portions 162 that protrude from one side surface and the other side surface of the power terminal 160 respectively and has a lower surface that is brought into contact with the internal connection frame 152. The connection portion 164a is sealed by the sealing member 190.

The exposed portion 164b has an opening 161 formed in a center portion of the exposed portion 164b; and a depressed portion 163 that is dented from other portions that are disposed at a position where the exposed portion 164b is brought into contact with a surface of the sealing member 190 (a connecting region with the connection portion 164a). The exposed portion 164b is exposed from the sealing member 190. The depressed portion 163 is formed in a state where the depressed portion 163 surrounds the entire circumference of the power terminal 160.

The power terminal 160 is formed by applying shearing to a flat plate material having conductivity, for example, a metal plate. As illustrated in FIG. 3C, one side surface 165a of the power terminal 160 is a shear droop surface where a shear droop 168a is formed at an end portion of the one side surface 165a, and the other surface 165b of the power terminal 160 is a burred surface that is connected with a fracture surface 168b on a side surface. In the depressed portion 163, an end portion of the other surface 165b of the power terminal 160 is dented than other portions of the other surface 165b of the power terminal 160 (see FIG. 3D).

The sealing member 190 seals the electronic elements 120A, 120B, a lower surface of the first terminal 130, a lower surface of the second terminal 140, the first connection frame 132, the second connection frame 142 and the power terminal 160 (the first part 166 and the connection portion 164a of the second part). The sealing member 190 is made of a thermosetting molding material formed by adding a silica filler and the like to an epoxy resin that constitutes a main component. The sealing member 190 protects the electronic elements 120 from an environment such as heat, light and moisture.

The sealing member 190 includes a proximal portion covering portion 192 that covers a proximal portion of the power terminal 160 that protrudes from the sealing member 190 (a proximal portion of a portion of the power terminal 190 that protrudes from a height position of a surface of a region other than the proximal portion covering portion 192 in the sealing member 190) (see FIG. 1A and FIG. 1B). Further, the sealing member 190 also includes the pin terminal proximal portion covering portion 193 that covers the proximal portions of portions of the pin terminals 171, 174 or the pin terminals 182, 184 that protrude from the sealing member 190 (the proximal portions of the portions of the pin terminals 172, 174, or the pin terminals 182, 184 that protrude from a height position of a surface of a region other than the pin terminal proximal portion covering portion 193 in the sealing member 190). The proximal portion covering portion 192 and the pin terminal proximal portion covering portion 193 are formed in shapes such that the proximal portion covering portion 192 and the pin terminal proximal portion covering portion 193 protrude from other portions of the sealing member 190. The pin terminal base covering portion 193 collectively covers the proximal portions of two pin terminals. However, the pin terminal base covering portion 193 may cover the pin terminals one by one or may collectively cover all four pin terminals.

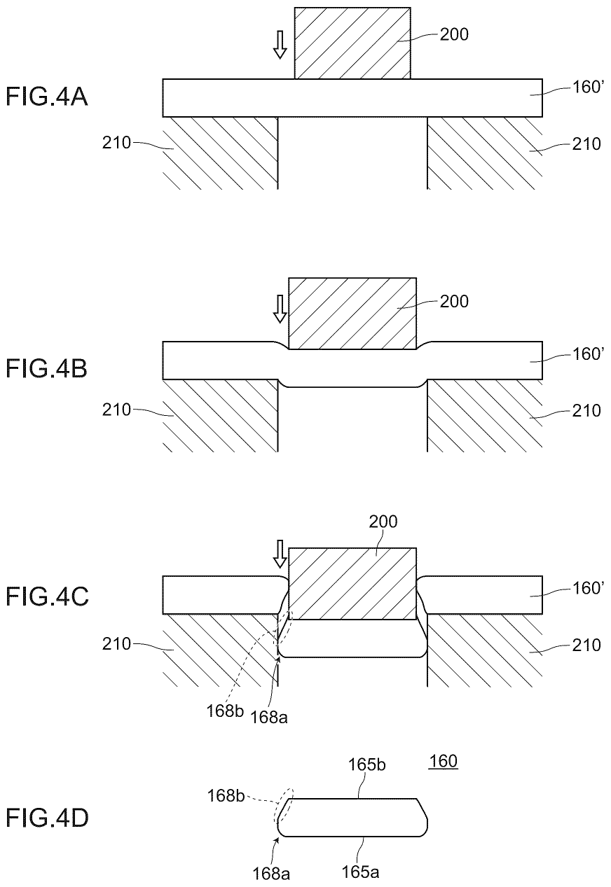

Next, the cross-sectional structure of the power terminal 160 in a horizontal direction and the depressed portion 163 are described with reference to FIG. 3A to FIG. 4D.

The power terminal 160 is manufactured by applying shearing working to a flat plate having conductivity (for example, a metal plate) using a press. To be more specific, as illustrated in FIG. 4A, a metal flat plate 160′ is disposed on a die 210 having an opening, and press working is performed by pressing the metal flat plate 160′ from above using a punch 200. In such an operation, a tensile stress is generated at a portion of the metal plate 160′ close to blades of the punch 200 and the die 210, and a shear droop 168a is generated on a surface of the metal flat plate 160′ (see FIG. 4C). When a load of the punch 200 is further increased, cracks occur in the metal flat plate 160′ so that the metal flat plate 160′ and the power terminal 160 are separated from each other (see FIG. 4C) whereby the power terminal 160 can be manufactured (see FIG. 4D). At this point of time, there may be a case where the burrs are formed on a shear surface. However, the burrs can be removed by polishing. The power terminal 160 is formed in this manner.

As described above, the power terminal 160 is manufactured by applying shearing to the metal flat plate and hence, a burr surface and a shear droop surface are formed. One side surface 165a of the power terminal 160 forms the shear droop surface and the other side surface 165b of the power terminal 160 forms the burr surface.

As illustrated in FIG. 3C, one side surface 165a of the power terminal 160 is the shear droop surface where the shear droop 168a having a round-shaped surface or an oblique surface is formed at an end portion. The other side surface 165b of the power terminal 160 is the burr surface that is contiguously connected with the fracture surface 168b of a side surface of the power terminal 160. An end portion of the other side surface 165b is relatively flat. The fracture surface 168b is formed on the side portion of the power terminal 160, and constitutes an oblique surface that is dented toward a burr surface side from the side surface on a shear droop 168a side.

The depressed portion 163 is formed so as to surround the entire circumference of the power terminal 160. In the depressed portion 163, one side surface 165a of the power terminal 160 is formed in a shape where the shear droop surfaces of other portions are depressed as it is.

On the other side surface 165b of the power terminal 160, a recessed portion 168c that is dented than other portions on the other surface of the power terminal 160 is formed. Further, on the side portion of the power terminal 160, when the depressed portion 163 of the power terminal 160 is formed (when the power terminal 160 is clamped by a pair of slide portions 24 in a sealing step described later), a depressed material is extruded to the side surface to form an extruded portion 169.

### 2. Method of Manufacturing Electronic Module and Manufacturing Device 1 (Die) of Electronic Module According to Embodiment

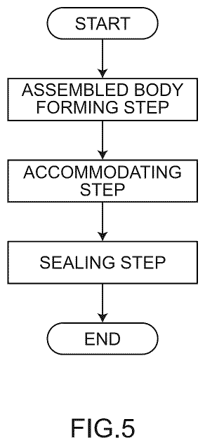

Next, the method of manufacturing an electronic module according to the embodiment is described. As illustrated in FIG. 5, the method of manufacturing an electronic module according to the embodiment includes an assembled body forming step, an accommodating step and a sealing step in this order.

### (Assembled Body Forming Step)

First, the power terminal 160 formed in a flat shape is erected upright on the board 110 on which the electrode elements 120A, 120B are disposed thus forming an assembled body that includes the board 110, the electronic elements 120A, 120B, the first terminal 130, the second terminal 140, the first connection frame 132, the second connection frame 142, the internal connection frame 152, and the power terminal 160.

To be more specific, on the circuit wiring 111 of the board 110, the electronic elements 120A, 120B are disposed via a conductive bonding material (for example, solder). Next, a lead frame where the first terminal 130, the second terminal 140, the first connection frame 132, the second connection frame 142, and the internal connection frame 152 are surrounded by a frame body portion (not illustrated in the drawing) is prepared and, then, the lead frame is disposed over the circuit wiring 111. At this stage of the step, the through hole formed in the first connection frame 132 and the through hole formed in the internal connection frame 152 are arranged to be positioned on electrodes (source electrodes) of the electronic elements 120A, 120B respectively.

Next, the first part 166 of the power terminal 160 is inserted into the elongated hole 156 formed in the lead frame (internal connection frame), the internal connection terminals 134, 154 are inserted into through holes, the pin terminals 172, 174, 182, 184 are inserted into predetermined portions of the lead frame respectively, and the power terminal 160 and the respective pin terminals are brought into contact with the board 110 and, at the same time, the internal connection terminals 134, 154 are brought into contact with the source electrodes of the electronic elements 120A, 120B. In performing such an operation, the power terminal 160, the internal connection terminals 134, 154 and the respective pin terminals may be inserted into the lead frame in advance and, the board 110 and the electronic elements 120A, 120B may be disposed on the circuit wiring 111 together with the lead frame.

Next, the board 110, the electronic elements 120A, 120B, the first terminal 120, the second terminal 140, the first connection frame 132, the second connection frame 142, the internal connection frame 152 and the power terminal 160 are electrically connected with each other by bonding them suitably. As a method of electrically bonding these members, for example, a case is considered where a conductive bonding material (solder) is disposed on connection portions in advance, the respective members are brought into contact with each other, and the respective members are bonded to each other by melting a conductive bonding material by reflowing or the like.

### (Configuration of Die 1)

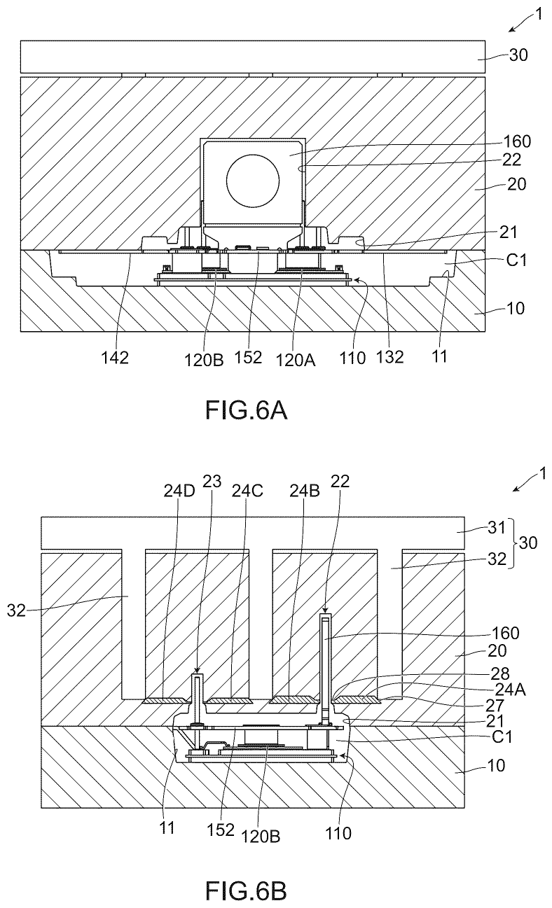

Before describing the accommodating step, first, the die 1 that is an electronic module manufacturing device according to the embodiment that accommodates the assembled body is described. As illustrated in FIG. 6A and FIG. 6B, the die 1 includes a first die 10, a second die 20 that opposedly faces the first die 10, and a drive member 30. The respective members can be moved in the up-and-down direction.

The first die 10 has: a first recessed portion 11 that is formed on an opposedly facing surface that opposedly faces the second die 20; and a mounting portion on which the frame body portion of the lead frame not illustrated in the drawing is mounted.

The second die 20 has: a second recessed portion 21 formed on an opposedly facing surface that opposedly faces the first die 10; and a power terminal accommodating hole 22 and a pin terminal accommodating hole 23 that extend upward from the second recessed portion 21. Slide portions 24 (24A to 24D) are disposed on an inner side portion of the power terminal accommodating hole 22 and the pin terminal accommodating hole 23. By moving the second die 20 toward the first die 10 thus joining the first die 10 and the second die 20 to each other whereby a first cavity C1 is formed by the first recessed portion 11 and the second recessed portion 21.

A pair of slide portions 24 are disposed on an inner side portion of the power terminal accommodating hole 22 and an inner side portion of the pin terminal accommodating hole 23. By sliding the pair of slide portions 24 in the horizontal direction thus protruding distal end portions of the slide portions 24 from an inner periphery of the power terminal accommodating hole 22 and hence, the power terminal 160 and respective pin terminals accommodated in the power terminal accommodating hole 22 and the pin terminal accommodating hole 23 can be clamped by the pair of slide portions 24. With such a configuration, it is possible to separate respective distal end portions 28 of the power terminal accommodating hole 22 and the pin terminal accommodating hole 23 from the first cavity C1 on a board side. The distal end portion of the pair of slide portions 24 are formed in a tapered shape.

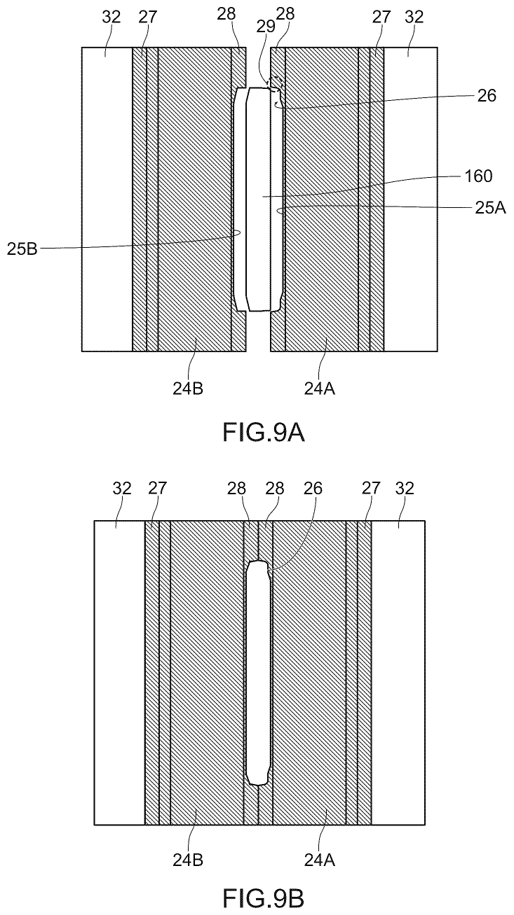

As illustrated in FIG. 9A and FIG. 9B, as viewed in a plan view, the recessed portions 25A, 25B that correspond to a cross section of the power terminal 160 are formed on distal end portions 28 of the pair of slide portions 24A, 24B respectively. With respect to the pair of slide portions 24A, 24B, a shape of a bottom of the recessed portion 25B in the slide portion 24B that is brought into contact with the power terminal 165a (shear droop surface) has a shape that corresponds to a shape of the shear droop surface. The shape of a bottom of the recessed portion 25A in the slide portion 24A that is brought into contact with the power terminal 165b (burr surface) has a shape where a protruding portion 26 is formed on both side wall sides of the recessed portion 25B. Further, a cutaway portion 29 that forms the extruded portion 169 (see FIG. 4A to FIG. 4D) is formed on a portion of a shoulder of at least one of the recessed portions 25A, 25B.

The drive member 30 includes a body portion 31 and pressing portions 32. The body portion 31 is disposed on the second die 20 (a side opposite to a first die 10 side), and is configured to be movable in the up-and-down direction. The pressing portions 32 are brought into contact with oblique surfaces 27 of the slide portions 24 on a proximal end portion side. When the body portion 31 of the drive member 30 approaches the second die 20, the pressing portions 32 press the oblique surfaces 27 of the slide portions 24 on a proximal end portion side (a side opposite to a distal end side of the power terminal) and hence, the pair of slide portions 24 is made to slide toward the power terminal 160. Further, by pulling out a separation pin not illustrated in the drawing, the pressing portions 32 (drive member 30) are moved upward along the oblique surfaces 27 on the proximal end portion side and, at the same time, the pair of slide portions 24 is made to slide in the directions away from each other.

### (Accommodating Step)

Next, the accommodating step is described. As illustrated in FIG. 6A and FIG. 6B, in the accommodating step, the board 110, the electronic elements 120A, 120B and a first part 166 of the power terminal 160 on a board side are accommodated in the first cavity C1 in the die 1, at the same time, a second part 164 (to be more accurate, the exposed portion 164b) of the power terminal 160 on a distal end side is accommodated in the power terminal accommodating hole 22 formed in the die 1 that extends from the inner side of the first cavity C1.

To be more specific, first, the frame body portion (not illustrated in the drawing) of the lead frame not illustrated in the drawing is mounted on the opposedly facing surface of the first die 10, and the assembled body is disposed in the first recessed portion 11 of the first die 10. At this stage of the processing, the metal plate 113 for radiating heat of the board 110 is disposed in a state where the metal plate 113 is brought into contact with the first recessed portion 11. Next, as illustrated in FIG. 6A and FIG. 6B, the second die 20 is made to overlap with the first die 10. In such a state, the first cavity C1 formed of the first recessed portion 11 of the first die 10 and the second recessed portion 21 of the second die 20 is formed. In the first cavity C1, the board 110, the electronic elements 120A, 120B, the first terminal 130, the second terminal 140, the first connection frame 132, the second connection frame 142, the internal connection 152 and the first part 166 of the power terminal 160 are accommodated. Further, in the power terminal accommodating hole 22 formed in the second die 20 that extends from the inner surface of the first cavity C1, an upper portion (exposed portion 164b) of the second part 164 of the power terminal 160 is accommodated. In the pin terminal accommodating hole 23 formed in the second die 20 that extends from the inner surface of the first cavity C1, upper portions of the pin terminals 172, 174, 182, 184 are accommodated.

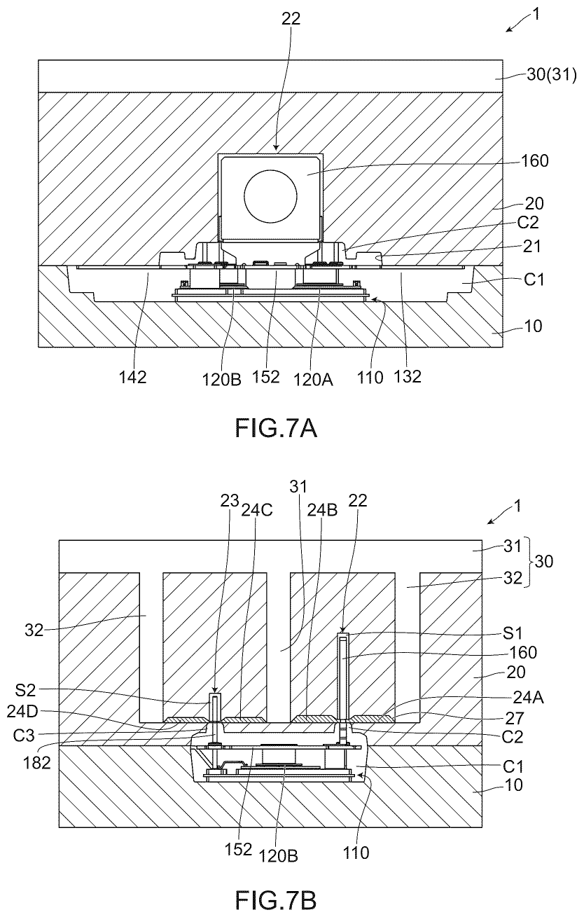

In the accommodating step, the power terminal 160 and the respective pin terminals are accommodated in the power terminal accommodating hole 22 and the pin terminal accommodating holes 23 and, thereafter, the pair of slide portions 24 is made to slide (protrude) from the inner peripheries of the power terminal accommodating hole 22 and the respective pin terminal accommodating holes 23 thus allowing the pair of slide portions 24 to clamp the second part 164 of the power terminal 160 and the respective pin terminals (see FIG. 7A and FIG. 7B). The position at which the slide portions 24 clamp the power terminal 160 is the position spaced apart from the internal connection frame 152 of the second part 164 by a predetermined length.

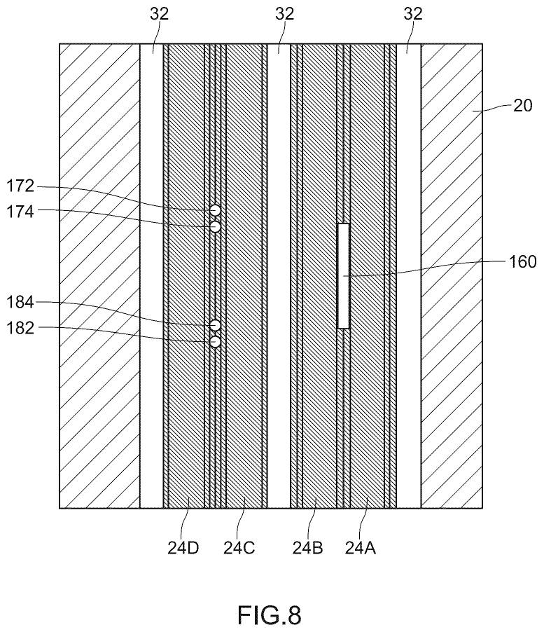

In allowing the slide portions 24 to clamp the power terminal 160, the body portion 31 of the drive member 31 is moved toward the second die 20 (see FIG. 7A, FIG. 7B and FIG. 8). With such an operation, the pressing portions 32 press the oblique surfaces 27 of the pair of slide portions 24 on a proximal end portion side and hence, the slide portions 24 simultaneously slide, can simultaneously clamp the power terminal 160. In the same manner, the respective pin terminals can be simultaneously clamped by the pair of slide portions 24.

At this stage of the processing, distal end portions of the pair of slide portions 24 (slide portions 24A, 24B) bite into an outer periphery of the power terminal 160 so that the depressed portion 163 is formed. Further, in a state where the pair of slide portions 24 clamp the power terminal 160 therebetween, the power terminal 160 is surrounded by the inner periphery of the power terminal accommodating hole 22 and the slide portions 24 and hence, a second cavity C2 is formed in a space associated with the first cavity C1 (see FIG. 7A and FIG. 7B). Further, a space that covers the exposed portion 166a of the power terminal 160 is spaced apart from the second cavity C2 by the slide portions 24.

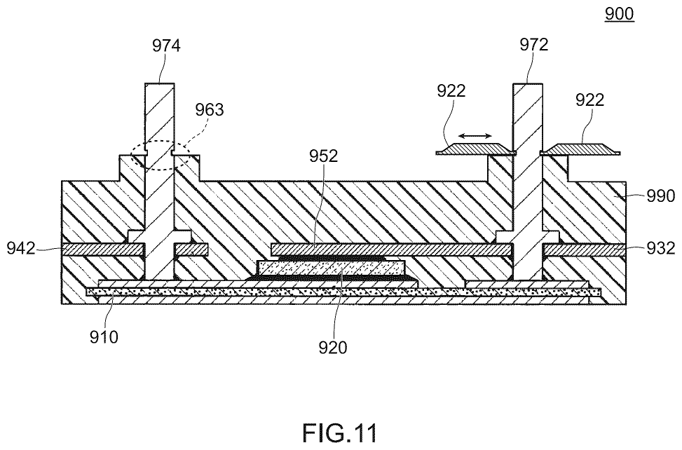

In the same manner, also with respect to the pin terminals, distal end portions of the pair of slide portions 24 (slide portions 24C, 24D) bite into an outer periphery of each pin terminal so that a dented portion is formed on the pin terminal (see symbol 963 in FIG. 11 with respect to the configuration of the recessed portion). In a state where the pair of slide portions (slide portions 24C, 24D) clamp the pin terminal, the pin terminal is surrounded by an inner periphery of the pin terminal accommodating hole 23 and the slide portions 24 so that a third cavity C3 is formed in a space associated with the first cavity C1. Further, a space that covers the distal end portion of each pin terminal by the slide portions 24 is spaced apart from the third cavity C3.

### (Sealing Step)

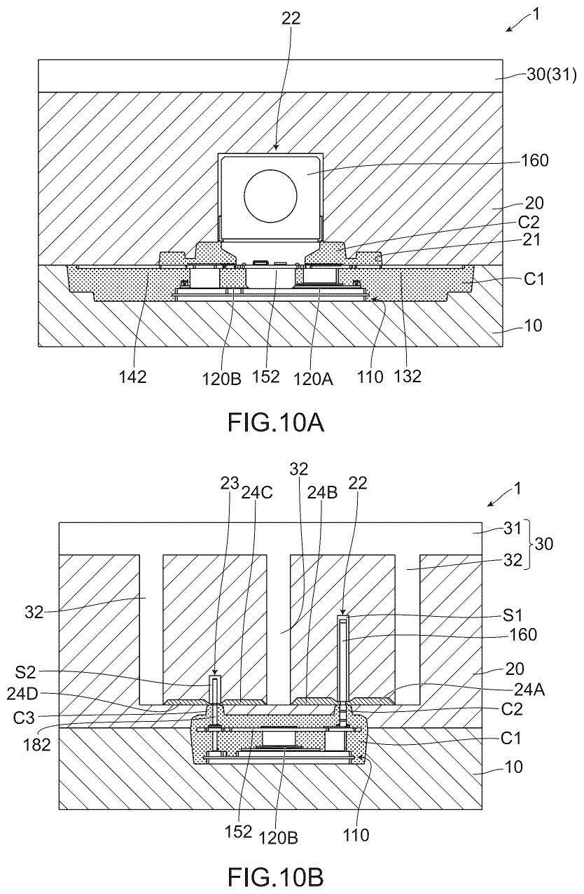

Next, the sealing member 190 (resin) is made to flow into the first cavity C1 thus sealing the board 110, the electronic elements 120 and the first part 166 of the power terminal 160 by the sealing member 190 (see FIG. 10A and FIG. 10B). Further, the sealing member 190 (resin) flows into the second cavity C2 from the first cavity C1 thus forming the proximal portion covering portion 192 and, at the same time, the sealing member 190 (resin) flows into also the third cavity C3 thus forming the pin terminal proximal portion covering portion 193.

After curing the resin that forms the sealing members 190 (including the proximal portion covering portion 192 and the pin terminal proximal portion covering portion 193), the electronic module 100 is taken out from the die 1. Then, the frame body portion of the lead frame (not illustrated in the drawings) is separated from the electronic module 100 by cutting. In this manner, the electronic module 100 can be manufactured.

### 3. Advantageous Effects Acquired by Electronic Module 100, the Method of Manufacturing Electronic Module and the Electronic Module Manufacturing Device 1 According to the Embodiment

According to the electronic module 100 of the embodiment, the power terminal 160 has the depressed portion 163 that is dented than other portions at the position where the power terminal 160 is brought into contact with the surface of the sealing member 190. Accordingly, at the time of performing sealing using the die 1, a gap is minimally formed between the die 1 (slide portions 24) and the power terminal 160 and hence, the occurrence of leakage of a resin can be prevented. As a result, the electronic module 100 according to the embodiment becomes an electronic module where leakage of a resin minimally occurs in the sealing step in spite of the use of the plate-shaped power terminal 160.

Further, according to the electronic module 100, and the method of manufacturing the electronic module of the embodiment, the electronic module 100 includes the internal connection frame 152 that is a flat-plate-shaped member having the elongated hole 156 (see FIG. 2B), supports the power terminal, and electrically connects the electronic elements 120A, 120B and the power terminal 160 with each other. Accordingly, the plate-shaped power terminal can be supported in a stable manner. Further, the circuit wiring can be constituted of the internal connection frame 152 and the power terminal 160 and hence, a mounting area for mounting the wiring on the board can be made small thus enabling downsizing of the electronic module. Further, the circuit wiring can be constituted in a stereoscopic space and hence, it is possible to provide the electronic module having high degree of freedom in designing.

Further, according to the electronic module 100 of the embodiment, in the power terminal 160, the first part 166 that is positioned on a board side of the inner connection frame 152 is press-fitted into the elongated hole 156 and hence, the power terminal 160 can be supported in a stable manner. Further, the close contact property between the internal connection frame 152 and the power terminal 160 can be increased. Still further, the second part 164 that is positioned on a side opposite to the board side of the internal connection frame 152 is formed with a width greater than a width of the first part 166 and hence, a cross-sectional area of a current path is increased thus facilitating the flow of a large current.

Further, according to the electronic module 100 of the embodiment, at the depressed portion 163, the end portion of the other surface 165b (burr surface) of the power terminal 160 is dented than the other portions of the other surface 165b of the power terminal 160. Accordingly, in the sealing step, it is possible to make the slide portions 24 bite into the other surface 165b of the power terminal 160 and hence, it is possible to prevent leakage of a resin from a fracture surface with certainty. Even when it is intended to remove a gouge (a portion of an end portion on a burr surface side retracted toward an inside) in the vicinity of a fracture surface, a depressed wall portion does not move toward the gouge. However, an end portion of the other surface 165b (burr surface) of the power terminal 160 is dented than other portions of the other surface 165b of the power terminal 160 and hence, such a gouge can be filled up.

According to the electronic module 100 of the embodiment, the depressed portion 163 is formed so as to surround the entire circumference of the power terminal 160 and hence, in the sealing step, it is possible to make the slide portions 24 bite into the entire plate-shaped power terminal 160 and hence, leakage of a resin can be prevented with more certainty.

Further, according to the electronic module 100 of the embodiment, at the depressed portion 163, on a side surface of the power terminal 160, the release portion 169 that protrudes toward the outside is formed and hence, in the accommodating step, a material of the plate member depressed by the slide portions 24 is extruded to the release portion 169. Accordingly, it is possible to prevent a phenomenon that the material is extruded to an unexpected portion so that the power terminal 160 is deformed, and a phenomenon that a gap is formed between the slide portions 24 and the power terminal 160 so that leakage of a resin occurs.

According to the electronic module 100 of the embodiment, the sealing member 190 has the proximal portion covering portion 192 that covers the proximal portion of the power terminal 160 that protrudes from the sealing member 190. Accordingly, a creepage distance from a portion that is exposed from the sealing member 190 such as the pin terminal 172 disposed adjacently to the power terminal 160 can be increased and hence, it is possible to provide an electronic module with minimum erroneous operations. Further, it is possible to protect the portion that is exposed from the sealing member 190 in the power terminal 160 that is weak against an impact and hence, it is possible to provide an electronic module having high impact resistance.

Further, the electronic module 100 according to the embodiment includes the pin terminals 172 or the like having a pin shape that are erected upright from the board 110, and the sealing member 190 has the pin terminal proximal portion covering portion 193 that covers the proximal portions of the pin terminals 172 that protrude from the sealing member 190. Accordingly, it is possible to increase a creepage distance from the portion that is exposed from the sealing member 190 at the power terminal 160 disposed adjacently to the pin terminals 172 and the like or other pin terminals and the like. Accordingly, it is possible to provide the electronic module with minimum erroneous operations. Further, it is possible to protect the portions of the power terminal 172 and the like that are exposed from the sealing member 190 and are weak against an impact and hence, also from this point of view, it is possible to provide an electronic module having high impact resistance.

According to the method of manufacturing the electronic module of the embodiment, by clamping the power terminal 160 by the pair of slide portions 24, the distal end portion of the power terminal 160 is separated from the first cavity C1, and at the time of clamping the power terminal 160 by the pair of slide portions 24, the distal end portions of the pair of slide portions 24A, 24B that protrude from the inner periphery of the power terminal accommodating holes 22 bite into the outer periphery of the second part 164 of the power terminal 160 thus forming the depressed portions 163. Accordingly, a gap is minimally formed between the die 1 (slide portions 24) and the power terminal 160 and hence, it is possible to prevent the occurrence of leakage of a resin.

According to the method of manufacturing the electronic module of the embodiment, both distal end portions of the pair of slide portions 24 are formed in a tapered shape. Accordingly, in the sealing step, at the time of clamping the power terminal 160, the depressed portion 163 can be easily formed on the power terminal 160 thus making the slide portions 24 bite into the power terminal 160. As a result, a gap minimally occurs between the power terminal 160 and the slide portions 24.

According to the method of manufacturing the electronic module and the electronic module manufacturing device of the embodiment, in the accommodating step, on the distal end portions of the pair of slide portions 24 of the die 1, the recessed portions 25A, 25B that correspond to the cross section of the power terminal 160 as viewed in a plan view are formed respectively. With respect to the pair of slide portions 24, the shape of the bottom of the recessed portion 25A of the slide portion 24A that is brought into contact with one side surface (shear droop surface) 165a has the shape that corresponds to the shape of the one side surface (shear droop surface) 165a. On the other hand, with respect to the pair of slide portions 24, the shape of the bottom of the recessed portion 25B of the slide portion 24B that is brought into contact with the burr surface has the shape where the protruding portion 26 is formed on both side wall sides of the recessed portion 25B. Accordingly, the depressed portion 163 that correspond to the difference between the shear droop surface and the burr surface can be formed and hence, it is possible to prevent leakage of a resin with more certainty.

According to the method of manufacturing the electronic module of the embodiment, the cutaway portion 29 is formed on shoulder portions of the recessed portions 25A, 25B of at least one (slide portion 24B) of the pair of slide portions 24.

Accordingly, in the accommodating step, at the time of forming the depressed portion by clamping the power terminal 160 with the slide portions 24, a material of the power terminal 160 moves to portions of the cutaway portion 29 and forms the release portion 169.

Although the present invention has been described based on the above-mentioned embodiment heretofore, the present invention is not limited to the above-mentioned embodiment. The present invention can be carried out in various modes without departing from the gist of the present invention. For example, the following modifications are also conceivable.
(1) The positions, the connections, the numbers and the like of the constitutional elements described in the above-mentioned respective (including the respective embodiments modifications) are provided for an exemplifying purpose, and these values can be suitably changed so long as the advantageous effects of the present invention are not impaired.
(2) In the above-mentioned embodiment, the present invention is applied to the electronic module that includes the pin terminals. However, the present invention is not limited to such a configuration. The present invention may be applied to an electronic module that does not use pin terminals.
(3) In the above-mentioned embodiment, the present invention is applied to the terminal that is used at the middle point terminal as the power terminal. However, the present invention is not limited to such a configuration. The present invention may be applied to the terminal other than the middle point terminal (for example, the first terminal, the second terminal).
(4) In the above-mentioned embodiment, the present invention is applied to the electronic module that includes the internal connection frame. However, the present invention is not limited to such a configuration. The present invention may be applied to the electronic module that does not include the internal connection frame.
(5) In the above-mentioned embodiment, the first die is used as an upper die, and the second die is used as a lower die. However, the present invention is not limited to such a configuration. The first die may be used as the lower die and the second die may be used as the upper die. In this case, the lead frame is disposed on the opposedly facing surface of the second die in a state where the power terminal and the pin terminal of the assembled body are inserted into the power terminal accommodating hole 22 and the pin terminal accommodating hole 23 formed in the second die. Then, a drive member is also disposed below the second die, and the pressing portion is moved upward so as to move the pair of slide portions in the horizontal direction.

1. An electronic module comprising:
a board;
an electronic element disposed on the board; and
a flat-plate-shaped power terminal being erected upright from the board, wherein
the board, the electronic element and the power terminal are sealed by a sealing member, and
the power terminal is configured such that at least a distal end portion of the power terminal protrudes from the sealing member, and the power terminal includes a depressed portion that is dented than the other portions of the power terminal at a position where the power terminal is brought into contact with a surface of the sealing member.

2. The electronic module according to claim 1 further comprising: an internal connection frame that is a flat-plate-shaped member having an elongated hole, the internal connection frame configured to support the power terminal and also configured to electrically connect the electronic element and the power terminal,
the sealing member is configured to seal the board, the electronic element, the internal connection frame, and the power terminal, and
in the power terminal,
a first part of the internal connection frame that is positioned on a board side is press-fitted in the elongated hole, and
a second part of the internal connection frame that is positioned on a side opposite to the board side is formed with a width greater than a width of the first part.

3. The electronic module according to claim 1, wherein
one side surface of the power terminal is a shear droop surface where a shear portion is formed at an end portion,
an other surface of the power terminal is a burr surface that is contiguously formed with a fracture surface of a side surface, and
at the depressed portion, an end portion of an other surface of the power terminal is dented than the other portions on the other surface of the power terminal.

4. The electronic module according to claim 1, wherein the depressed portion is formed in a state where the depressed portion surrounds an entire circumference of the power terminal.

5. The electronic module according to claim 1, wherein in the depressed portion, a release portion that protrudes toward an outside is formed on a side surface of the power terminal.

6. The electronic module according to claim 1, wherein the sealing member has a proximal portion covering portion that covers a proximal portion of a portion of the power terminal that protrudes from the sealing member.

7. The electronic module according to claim 1, further comprising a pin-shaped pin terminal that is erected upright from the board, at least a distal end portion of the pin terminal being protruding from the sealing member, wherein
the sealing member includes a pin terminal proximal portion covering portion that is configured to cover a proximal portion of a portion of the pin terminal that protrudes from the sealing member.

8. A method of manufacturing an electronic module comprising:
an assembled body forming step of forming an assembled body including a board, an electronic element and a power terminal having a flat-plate-shape by erecting upright the power terminal on the board on which the electronic element is disposed;
an accommodating step of accommodating the board, the electronic element and a first part of the power terminal on a board side in a first cavity of a die, and accommodating a second part of the power terminal on a distal end side into a power terminal accommodating hole that extends from an inner surface of the first cavity; and
a sealing step of sealing the board, the electronic element, and the first part of the power terminal by making a sealing material flow into the first cavity, wherein
in the accommodating step, the second part of the power terminal is inserted into the power terminal accommodating hole and, thereafter, distal end portions of a pair of slide portions mounted on the die are made to protrude from an inner periphery of the power terminal accommodating hole so as to clamp the power terminal by the pair of slide portions so that the distal end portion of the second part of the power terminal is separated from the first cavity and the distal end portions of the pair of slide portions bite into an outer periphery of the second part of the power terminal whereby a depressed portion is formed.

9. The method of manufacturing an electronic module according to claim 8, wherein distal end portions of both of the pair of slide portions are formed in a tapered shape.

10. The method of manufacturing an electronic module according to claim 8, wherein
one side surface of the power terminal is a shear droop surface where a shear droop is formed on an end portion of the one side surface,
an other side surface of the power terminal is a burr surface that is contiguously formed with a fracture surface of a side surface of the power terminal,
in the accommodating step, as viewed in a plan view, on distal end portions of the pair of slide portions of the die, a recessed portion that corresponds to a cross section of the power terminal is formed respectively,
with respect to the pair of slide portions, a shape of a bottom of the recessed portion of the slide portion that is brought into contact with the shear droop surface has a shape that corresponds to the shape of the shear droop surface, and
with respect to the pair of slide portions, a shape of a bottom of the recessed portion of the slide portion that is brought into contact with the burr surface is formed such that a protruding portion is formed on both side wall sides of the recessed portion.

11. The method of manufacturing an electronic module according to claim 8, wherein a cutaway portion is formed on a portion of a shoulder of a recessed portion in at least one of the pair of slide portions.

12. The method of manufacturing an electronic module according to claim 8, wherein
in the assembled body forming step, the assembled body is assembled including an internal connection frame that is a flat-plate-shaped member having an elongated hole, supports the power terminal, and electrically connects the electronic element and the power terminal to each other, the power terminal is supported by press-fitting the first part of the power terminal into the elongated hole, and the electronic element and the power terminal are electrically connected to each other, and
in the sealing step, the board, the electronic element, the internal connection frame and the power terminal are sealed by a sealing member, and
a second part of the power terminal is formed with a width greater than a width of the first part.

13. A manufacturing device of an electronic module for carrying out the method of manufacturing an electronic module according to claim 8, the manufacturing device comprising:
a first die that has the power terminal insertion hole and includes the pair of slide portions; and
a second die that opposedly faces the first die, wherein
one side surface of the power terminal is a shear droop surface where a shear droop is formed at an end portion,
an other surface of the power terminal is a burr surface that is contiguously formed with a fracture surface of a side surface, and
as viewed in a plan view, a recessed portion that corresponds to a cross section of the power terminal is formed on distal end portions of the pair of slide portions respectively,
with respect to the pair of slide portions, a shape of a bottom of the recessed portion of the slide portion that is brought into contact with the shear droop surface has a shape that corresponds to the shape of the shear droop surface, and
with respect to the pair of slide portions, a shape of a bottom of the recessed portion of the slide portion that is brought into contact with the burr surface is formed such that a protruding portion is formed on both side wall sides of the recessed portion.
